(19) United States
(12) Patent Application Publication
(10) Pub. No.: US 2004/0252035 A1
(43) Pub. Date: Dec. 16, 2004

(54) Method and apparatus for inputting Chinese pinyin with tone markers

(75) Inventor: Sun-Ny Chang, Suwon-shi (KR)

Correspondence Address: DILWORTH & BARRESE, LLP, 333 EARLE OVINGTON BLVD., UNIONDALE, NY, 11553, US

(73) Assignee: SAMSUNG ELECTRONICS CO., LTD., KYUNGKI-DO (KR)

(21) Appl. No.: 10/631,652

(22) Filed: Jul. 31, 2003

(30) Foreign Application Priority Data
Apr. 22, 2003 (KR) 2003-25432

(51) Int. Cl. H03K 17/94

(52) U.S. Cl. 341/28

(57) ABSTRACT

A method and an apparatus for inputting Chinese pinyin with tone markers, in which predetermined keys are assigned to input pinyin vowels with a tone marker. When a key is pressed to input a vowel that can have a tone marker, the predetermined keys are activated to enable a user to input a desired vowel with a tone marker. When one of the activated keys is pressed, a corresponding vowel with a tone marker is displayed at the same position of the previously inputted vowel.

### PRIORITY

This application claims priority to an application entitled “Method and Apparatus for Inputting Chinese Pinyin with Tone Markers” filed in the Korean Intellectual Property Office on Apr. 22, 2003 and assigned Serial No. 2003-25432, the contents of which are hereby incorporated by reference.

### BACKGROUND OF THE INVENTION

1. Field of the Invention

The present invention relates to a method and an apparatus for inputting Chinese pinyin with tone markers.

2. Description of the Related Art

The Chinese language consists of Chinese characters, pinyin and tones. Chinese characters convey meanings, pinyin is the representation of the pronunciation of each Chinese character, and tones refer to different pitching of sound. Conventional Chinese input methods include a pinyin input method; a Chinese S(T) stroke method, which selects a Chinese character according to the stroke order in writing the character; and a quick English or another English method for inputting pinyin without tone markers.

Among these Chinese input methods, pinyin input and Chinese S(T) stroke require complicated inputs of Chinese characters. Thus, the English method which inputs pronunciations of Chinese characters is generally preferred.

More specifically, the English method is to input pinyin pronunciations of Chinese characters using Roman letters. In pinyin, which is Chinese phonetic alphabet, there are four tones marked on top of the six main vowels a, e, i, o, u and ü. The 1^{st} tone that starts and stays high is marked with a horizontal line (or macron) above vowels. Vowels with the 1^{st} tone maker are \overline{a},\overline{e},\overline{i},\overline{o},\overline{u}, and \ddot{\overline{u}}. The 2^{nd} tone that starts low and rises is marked with an acute accent. Vowels with the 2^{nd} tone marker are á, é, í, ó, ú, and \ddot{\acute{u}}. The 3^{rd} tone that starts medium-low, falls to very low and then rises to medium high is marked with a symbol that looks like a “v”. Vowels with the 3^{rd} tone marker are \check{a}, \check{e}, \check{i}, \check{o}, \check{u}, and \ddot{\check{u}}. The 4^{th} tone that starts high and falls quickly to low is marked with a grave accent, similar to a backslash. Vowels with the 4^{th} tone marker are à, è, ì, ò, ù, and \ddot{\grave{u}}. Tones are very important in Chinese, because different tones for a syllable convey different meanings.

According to the conventional pinyin input methods, a separate keyboard is assigned to input pinyin with tone markers. For pinyin without tone markers, a conventional keyboard for inputting alphabetic characters is used. In order to input vowels with a tone marker, the user should convert the general keyboard to the pinyin keyboard.

FIG. 1 illustrates a pinyin keyboard for inputting vowels with a tone marker. Referring to FIG. 1, the user must convert the English keyboard to the pinyin keyboard and back to the English keyboard again in order to input a single pinyin word. Also, the user must memorize the positions of keys assigned to the vowels with a tone marker, because the positions of keys for the pinyin vowels are not identical to those of keys for the English vowels.

Because the pinyin keyboard must be selected to input vowels with a tone marker as illustrated in FIG. 1, the user may feel it is inconvenient to use the conventional pinyin input methods. Further, the input speed in the conventional methods is not satisfactory.

Therefore, a need exists for an improved apparatus and method for inputting Chinese pinyin with tone markers.

### SUMMARY OF THE INVENTION

Accordingly, the present invention has been designed to solve the above and other problems occurring in the prior art, and an object of the present invention is to provide a method and an apparatus for easily inputting Chinese pinyin with tone markers.

In order to accomplish the above and other objects, there is provided a Chinese pinyin input apparatus comprising: a user interface comprising keys for inputting pinyin; a display section for displaying pinyin; a memory for storing vowels with a tone marker to correspond to respective keys on the user interface; and a control section for, when a vowel that can have a tone marker is inputted, displaying a series of vowels having the same sound as the inputted one and having different tone markers, together with predetermined corresponding keys, on the display section, and when any of the keys corresponding to the series of vowels is selected, displaying a vowel with a tone marker corresponding to the selected key.

### BRIEF DESCRIPTION OF THE DRAWINGS

The above and other objects, features and advantages of the present invention will be more apparent from the following detailed description taken in conjunction with the accompanying drawings, in which:

FIG. 1 illustrates a pinyin keyboard for inputting vowels with a tone marker; [LABER “PRIOR ART”.]

FIG. 2 illustrates conventional construction of a Chinese pinyin input apparatus according to a first embodiment of the present invention;

FIG. 3 is a flow chart illustrating a process of inputting pinyin in the pinyin input apparatus according to the first embodiment of the present invention;

FIG. 4 illustrates a construction of a Chinese pinyin input apparatus according to a second embodiment of the present invention;

FIG. 5 illustrates a user interface of a Chinese pinyin input apparatus which is applicable in the present invention;

FIG. 6 is a flow chart illustrating a process of inputting pinyin in the pinyin input apparatus according to the second embodiment of the present invention; and

FIGS. 7A to 7K illustrate an example of inputting pinyin words in the pinyin input apparatus according to the first and second embodiments of the present invention.

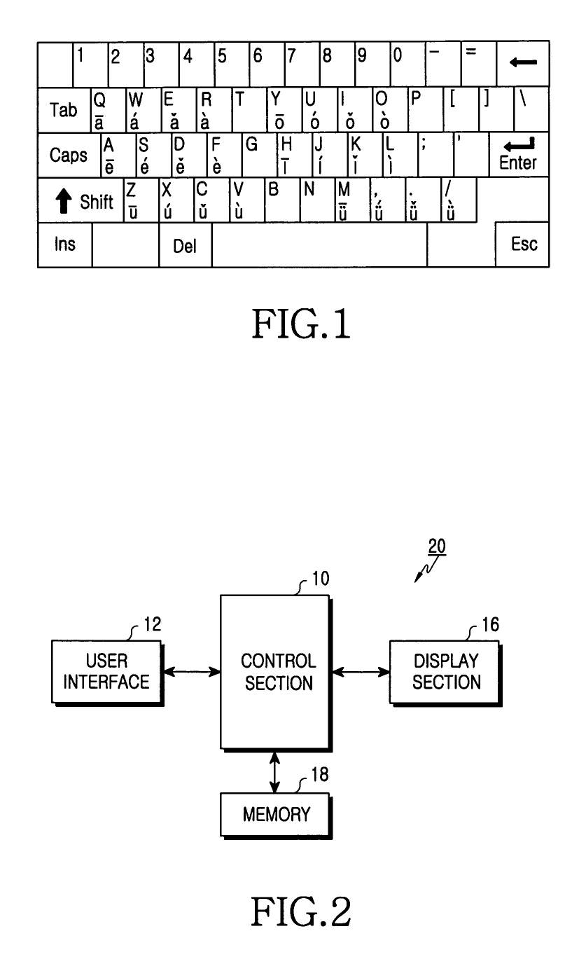

### DETAILED DESCRIPTION OF THE PREFERRED EMBODIMENT

Preferred embodiments of the present invention will be described in detail hereinbelow with reference to the accompanying drawings. In the following description of the present invention, a detailed description of known functions and configurations incorporated herein will be omitted when it may make the subject matter of the present invention rather unclear.

FIG. 2 illustrates a construction of a pinyin input apparatus according to the first embodiment of the present invention. Referring to FIG. 2, the pinyin input apparatus 20 according to the first embodiment can be implemented in a computer or similar electronic device. The pinyin input apparatus 20 includes a user interface 12, which enables a user to input Pinyin words. For example, the user interface 12 can be a keyboard or a touch screen. When the user interface 12 is a touch screen, it is possible to select and input number keys, function keys, and arrows displayed on the touch screen using an input means, such as a stylus pen. The pinyin input apparatus 20 also includes a memory 18 for storing vowels with a tone marker, numbers, and alphabetic characters to be displayed on a display section 16 by the selection of corresponding inputs, e.g., keys, on the user interface.

When a pinyin word is input from the user interface 12, a control section 10 of the pinyin input apparatus 20 displays tones which can be marked on top of six main vowels, enabling the user to select a proper tone by a key input. More specifically, when a vowel, which can have a tone marker, is input from the user interface 12 the control section 10 displays a series of vowels having the same sound as the input one and having different tone markers on the display section 16. At this time, the control section 10 can display, for example, only the number keys corresponding to those displayed vowels, without displaying other keys for inputting pinyin.

For example, if the user selects a vowel “a” in a pinyin input mode, the control section 10 will display “0:a, 1:\overline{a}, 2:á, 3:\check{a}, 4:à” on the display section 16. The user can then select a desired vowel by inputting a corresponding number key. More specifically, number key “0” is input to select a vowel “a” having no tone marker, number key “1” is input to select a vowel “\overline{a}” in the first tone, number key “2” is input to select a vowel “á” in the second tone, number key “3” is input to select a vowel “\check{a}” in the third tone, and number key “4” is input to select a vowel “à” in the fourth tone.

As described above, if the user inputs a vowel that can have a tone marker, the control section 10 will display a series of vowels having the same sound as the input one and having the different tone markers. When the user selects a desired one among the displayed vowels by inputting a corresponding number key, the control section 10 will display the selected vowel on the display section 16. According to the present invention, the user can easily input a vowel with a tone marker through a selection window showing vowels that can have a tone marker.

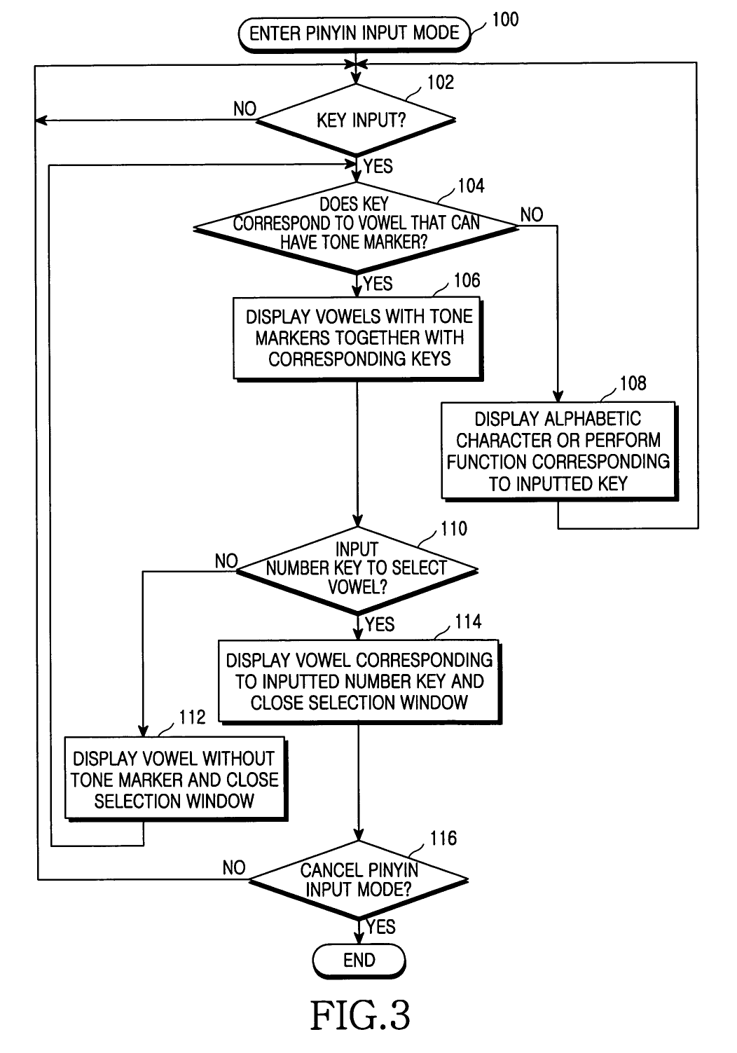

FIG. 3 is a flow chart illustrating a process of inputting pinyin in the pinyin input apparatus according to the first embodiment of the present invention. Referring to FIG. 3, in step 100, the pinyin input apparatus 20 enters a pinyin input mode according to user's selection or a control by the control section 10. In the pinyin input mode, the control section 10 of the pinyin input apparatus 20 waits for a key input at step 102. When the user inputs a particular key, the control section 10 determines whether the input key corresponds to a vowel that can have a tone marker in step 104. In step 106, if the input key selects a vowel that can have a tone marker, the control section 10 will display a selection window including vowels with different tone markers, on the display 16, so that the user can select a desired vowel with a tone marker. For example, if the user selects a vowel “a” in the pinyin input mode, the control section 10 will display a selection window showing “0:a, 1:\overline{a}, 2:á, 3:\check{a}, 4:à” so that the user can select a desired vowel by inputting a corresponding number key. Although different number keys are assigned to vowels with different tone markers in the first embodiment, it should be noted that any keys other than the number keys can be used to enable the user to easily select vowels with a tone marker.

In step 110, the control section 10 determines whether the user inputs a key corresponding to a vowel with a tone marker. If the user wishes to select a vowel without a tone marker, the user can press either the number key “0” or any key other than the number keys assigned to the vowels with a tone marker. If the user inputs a number key corresponding to a vowel with a tone marker, the control section 10 displays the vowel corresponding to the input key on the display section 16 and close the selection window in step 114. For example, if the user presses number key “3” in the selection window showing “0:a, 1:\overline{a}, 2:á, 3:\check{a}, 4:à”, the vowel “\check{a}” in the third tone will be selected and displayed on the display section 16.

In step 112, if the user does not press any number key for selecting a vowel with a tone marker, the control section 10 displays the vowel without a tone marker, i.e., “a”, on the display section 16 and returns the to step 104 to determine whether a next key input by the user corresponds to a vowel that can have a tone marker.

In step 104, if the control section 10 determines that a key input in step 102 does not correspond to a vowel that can have a tone marker, the control section 10 displays an alphabetic character or perform a function corresponding to the input key in step 108.

To summarize, with respect to the six main vowels that can have a tone marker, the pinyin input apparatus and method according to the first embodiment of the present invention assign different number keys to vowels with different tone markers. When a key is pressed to input any of the six main vowels, keys assigned to a series of vowels having the same sound as the input one and having different tone markers are activated. When the user presses one of the activated keys, a corresponding vowel with a tone marker is displayed.

As described above, the first embodiment of the present invention can be easily implemented when using a user interface having a plurality of keys, such as a keyboard of a computer. A method and an apparatus for easily inputting Chinese pinyin in hand-held devices, such as mobile communication terminals, which are increasing in demand in China, will be described below in detail.

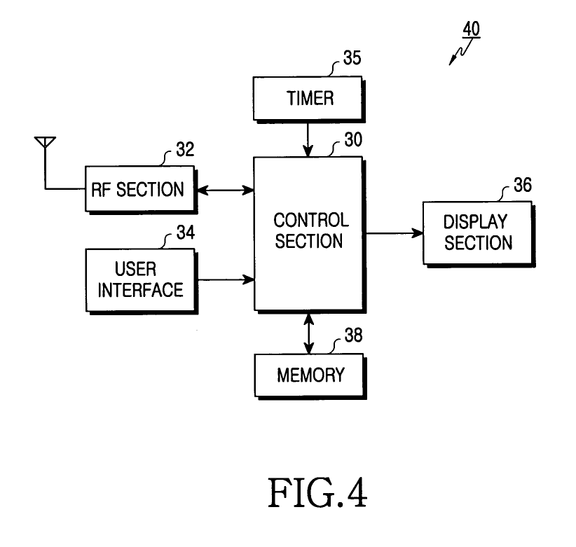

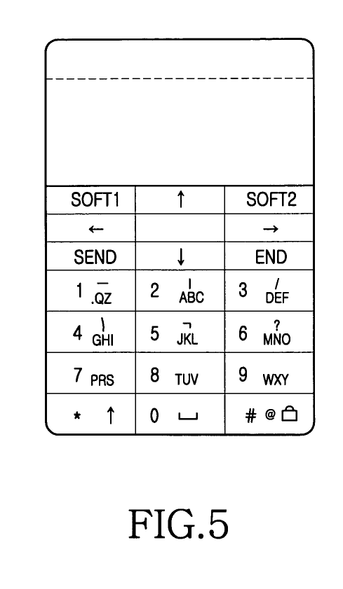

FIG. 4 illustrates a construction of a pinyin input apparatus according to a second embodiment of the present invention, and FIG. 5 illustrates a user interface of the pinyin input apparatus which is applicable in the present invention.

Referring to FIG. 4, a pinyin input apparatus 40 according to the second embodiment of the present invention can be readily implemented in a hand-held device, such as a mobile communication terminal or a digital hybrid mobile terminal. The pinyin input apparatus 40 includes a user interface 34, which enables a user to input pinyin words. As illustrated in FIG. 5, the user interface 34 can be a touch screen or a general keypad having a smaller number of keys than a computer keyboard. When the user interface 34 is a touch screen, it is possible to select and input number keys, function keys, and arrows displayed on the touch screen using an input means, such as a stylus pen. The pinyin input apparatus 40 also includes a memory 38 for storing vowels with a tone marker, numbers, and alphabetic characters to be displayed on a display section 36 by the selection of corresponding keys on the user interface 34. The pinyin input apparatus 40 includes an RF (radio frequency) section 32 connected to a control section 30. The RF section 32 transmits or receives a radio signal to or from a base station for a mobile communication system through an antenna. Unless the pinyin input apparatus 40 according to the second embodiment of the present invention is implemented in a mobile communication terminal or a digital hybrid mobile terminal, the RF section 32 will not be an essential element of the pinyin input apparatus 40.

When one of the six main vowels that can have a tone marker is input from the user interface 34, the control section 30 of the pinyin input apparatus 40 activates predetermined keys for a predetermined period of time to input vowels with a tone marker. To this end, the pinyin input apparatus 40 comprises a timer 35 for counting the time for key activation. It is obvious to one skilled in the art that the timer 35 can also be included in the control section 30.

More specifically, when the user inputs a vowel that can have a tone marker, the control section 30 of the pinyin input apparatus 40 activates predetermined keys for inputting a series of vowels having the same sound as the input one and having different tone markers. According to the second embodiment, the user interface 34 is a keypad of a mobile communication terminal. One number and two or more alphabetic characters are assigned together to each key on the keypad. When a vowel that can have a tone marker is input, keys excluding a plurality of keys with alphabetic characters for inputting pinyin and a few function keys for operating the mobile communication terminal are activated. Thus, it is difficult to input a vowel with a tone marker using the activated keys only. In the second embodiment of the present invention, keys with alphabetic characters for inputting pinyin and function keys are activated for a predetermined period of time to serve as keys for inputting vowels with a tone marker.

When the user inputs a vowel that can have a tone marker in the pinyin input mode, the control section 30 activates a predetermined number of keys, among keys with alphabetic characters and function keys on the user interface 34, for a predetermined period of time, to enable the user to select a desired vowel with a tone marker by the input of the activated keys. In other words, when a vowel that can have a tone marker is input, the control section 30 waits a predetermined period of time until a key for selecting a desired vowel is pressed or the time expires. When a key is pressed to select a desired vowel with a tone marker, the control section 30 displays the vowel with the tone marker and prepares to receive a next key input. At this time, the control section 30 can display keys corresponding to a series of vowels having the same sound as the input one and having different tone markers on the display section 36. When the predetermined period of time for selecting a vowel with a tone marker lapses or after the vowel with the tone marker is input, the control section 30 reconverts the keys activated to select any vowel displayed in a selection window to perform their original operational or input functions.

For example, when the user inputs a vowel “a”, the control section 30 will display a selection window showing “0:a, 1:\overline{a}, 2:á, 3:\check{a}, 4:à” on the display section 36 for a predetermined period of time so that the user can select a desired vowel by inputting a corresponding number key. For example, if the user presses number key “3” within the predetermined time period, the vowel “\check{a}” in the third tone will be selected and displayed on the display section 36. If the user presses the same key after lapse of the predetermined time period, the control section 30 will display the alphabetic character “d”, which is assigned to number key “3”, on the display section 36.

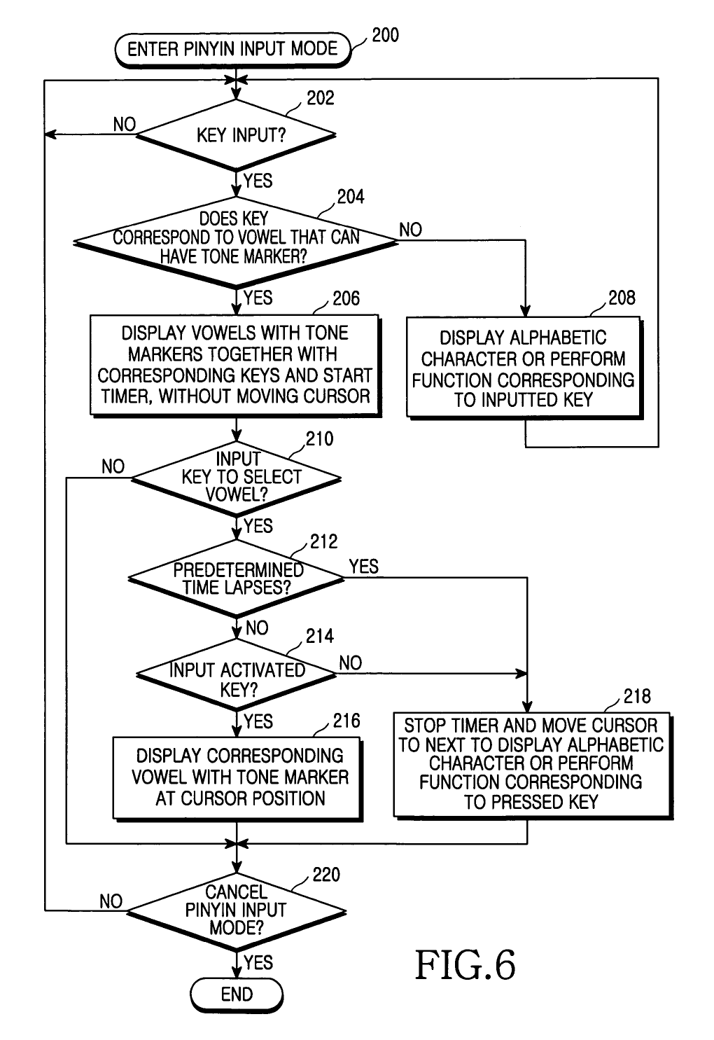

FIG. 6 is a flow chart illustrating a process of inputting pinyin in the pinyin input apparatus according to the second embodiment of the present invention. Referring to FIG. 6, in step 200, the pinyin input apparatus 40 can enter a pinyin input mode according to a user's selection or a control by the control section. In the pinyin input mode, the control section 30 of the pinyin input apparatus 40 waits for a key input in step 202. When the user presses a particular key, in step 204, the control section 30 determines whether the pressed key corresponds to a vowel that can have a tone marker. If the pressed key inputs a vowel that can have a tone marker, in step 206, the control section 30 displays a series of vowels having the same sound as the input one and having different tone markers, on the display section 36, and starts a timer for counting time. Also, the control section 30 places a cursor at the position of the input vowel when displaying a series of corresponding vowels on the display section 36 so that the user can input a desired vowel with a tone marker at the same position of the cursor.

In step 210, the control section 30 determines whether the user inputs a key corresponding to a vowel that can have a tone marker. If there is a key input, the control section 30 determines whether the time set by the timer has lapsed in step 212. As described above, the second embodiment of the present invention uses a keypad having a limited number of keys to input vowels with a tone marker. Thus, in the second embodiment, keys with alphabetic characters for inputting pinyin are activated for only a predetermined period of time to serve as keys for inputting vowels with a tone marker.

If the predetermined time has lapsed, in step 218, the control section 30 recognizes the key input by the user as a key for inputting an alphabetic character originally assigned thereto or for performing its original function, rather than a key for inputting a vowel with a tone marker. In step 218, the control section 30 moves the cursor to the next spot to display an alphabetic character or perform a function corresponding to the input key.

If the user inputs a key within the time set by the timer, in step 214, the control section 30 determines whether the input key is activated to input a vowel with a tone marker. Accordingly, if the user wishes to input a vowel with a tone marker, the user should input an activated key within the predetermined time period. The “predetermined time period” can be a time generally given to input a single character by one or more strokes in a mobile communication terminal. It is possible to set the time to a proper period for inputting a vowel with a tone marker in a mobile communication terminal. Also, it is possible to input any key other than those activated only for the predetermined time period to input a vowel with a tone marker, without waiting until the period lapses.

In the second embodiment of the present invention, keys which are assigned numbers are activated only for a predetermined period of time to input a vowel with a tone marker. However, keys activated to input a vowel with a tone marker are not limited to those assigned numbers. Any other keys can be used to enable the user to easily select a vowel with a tone marker.

In step 214, the control section 30 determines whether the user has pressed one of the keys activated for a predetermined period of time to input a vowel with a tone marker. If the key pressed by the user is a key for inputting a vowel with a tone marker, the control section 30 displays a vowel with a tone marker, which corresponds to the pressed key, at the current position of the cursor in step 216. If the pressed key is not to input a vowel with a tone marker, the control section 30 will proceed to step 218. In step 218, the control section 30 stops the timer and moves the cursor to the next spot to display an alphabetic character or perform a function corresponding to the pressed key.

With respect to the vowels that can have a tone marker, the pinyin input apparatus and method according to the second embodiment of the present invention activate predetermined keys for a predetermined period of time to enable the user to input vowels with a tone marker. In the second embodiment, as in the first embodiment, the pinyin input apparatus and method display keys corresponding to vowels with different tone markers on the display section 36 so that the user can select a desired vowel by pressing a corresponding key.

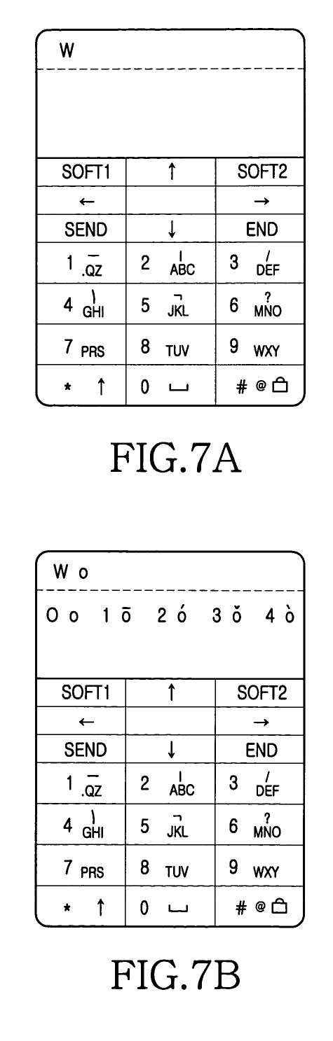

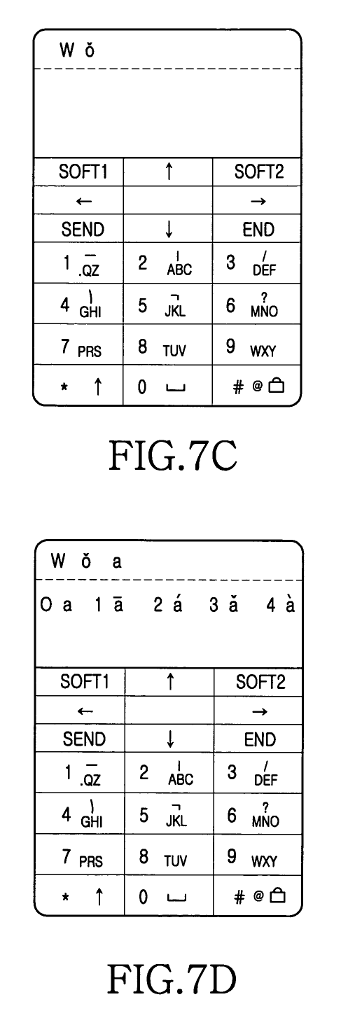

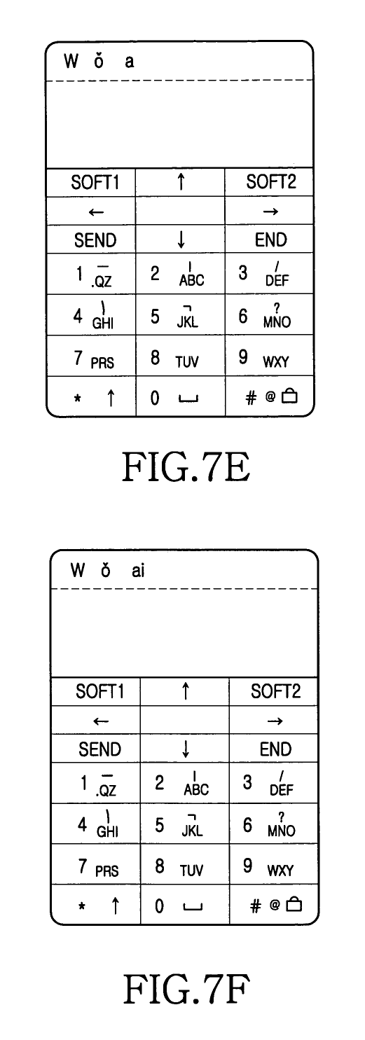

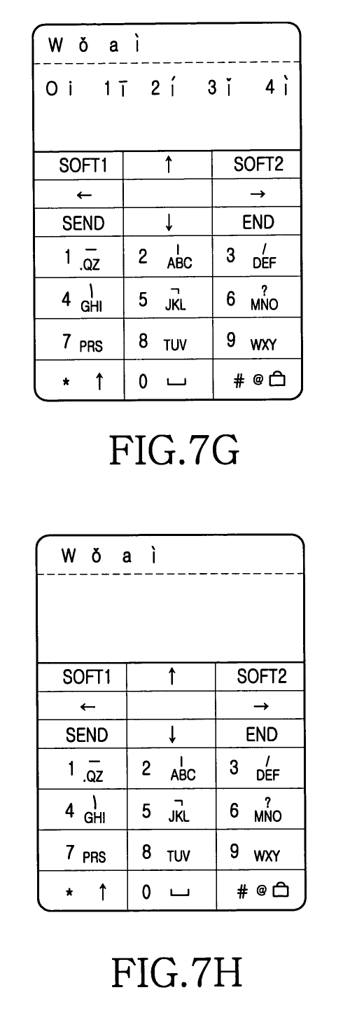

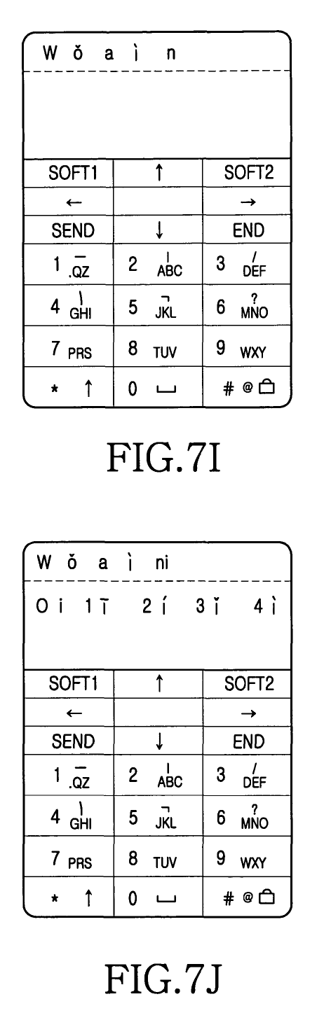

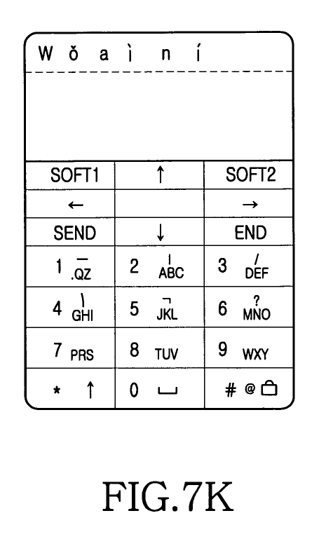

FIGS. 7A to 7K illustrate an example of inputting pinyin words in the pinyin input apparatus according to the first and second embodiment of the present invention.

FIGS. 7A to 7K illustrate a process of inputting pinyin words “W\check{o} aì ní”, meaning “I love you”.

Referring to FIG. 7A, when the user inputs a vowel “o” after an alphabetic character “W”, the pinyin input apparatus 40 displays the inputted vowel “o” as illustrated in FIG. 7B. The cursor is placed on the vowel “o”. The pinyin input apparatus 40 then displays a selection window showing “0:o, 1:\overline{o}, 2:ó, 3:\check{o}, 4:ò” on the display section 36. At the same time, the pinyin input apparatus 40 starts the timer and activates keys corresponding to the vowels with different tone markers. Referring to FIG. 7B, keys assigned numbers are activated to input a vowel with a tone marker. If the user inputs a key assigned number “3” within a predetermined period of time, the pinyin input apparatus 40 will display a corresponding vowel “\check{o}” in the third tone on the display section as illustrated in FIG. 7C.

When the user inputs a vowel “a” after “W\check{o}”, the pinyin input apparatus 40 displays a selection window showing “0:a, 1:\overline{a}, 2:á, 3:\check{a}, 4:à” on the display section 36 as illustrated in FIG. 7D, because the vowel “a” can have a tone marker. If the user wishes to input “a” without a tone marker (FIG. 7E), the user should press a key for inputting the following character after the predetermined time period or move the cursor to the next spot. Alternatively, the user can input the key assigned number “0” to input “a” without a tone marker. Subsequently, when the user inputs a vowel “i” (FIG. 7F) that can have a tone marker, the pinyin input apparatus 40 displays a selection window showing “0:i, 1:\overline{i}, 2:í, 3:\check{i}, 4:ì” on the display section 36 as illustrated in FIG. 7G If the user inputs a key assigned number “4” within the predetermined time period, the pinyin input apparatus 40 will display a corresponding vowel “i” in the fourth tone on the display section as illustrated in FIG. 7H.

When the user inputs “n” after “W\check{o} aì”, the pinyin input apparatus 40 displays “W\check{o} aì n” on the display section 36 as illustrated in FIG. 71. Subsequently, when the user inputs a vowel “i” that can have a tone marker, the pinyin input apparatus 40 displays “W\check{o} aì ni” on the display section 36 as illustrated in FIG. 7J. At the same time, the pinyin input apparatus 40 displays a selection window showing vowels with different tone markers. If the user inputs a key assigned number “2” within the predetermined time period, the pinyin input apparatus 40 will display a corresponding vowel “i” in the second tone on the display section 36 as illustrated in FIG. 7K.

As described above, in the present invention, the user can easily input a vowel with a tone marker.

Chinese characters in simplified or tradition form, although being useful in conveying correct meanings, cannot be easily inputted. Thus, it is required to use pinyin pronunciations to input Chinese. According to conventional pinyin input methods, a separate keyboard is arranged to input pinyin with tone markers. The present invention, however, activates predetermined keys to input vowels with a tone marker, without the need to arrange a separate keyboard. According to the present invention, existing keys with alphabetic characters or numbers can be used to input vowels with a tone marker simply by converting the mode of a pinyin input apparatus to the pinyin input mode. The present invention is also applicable to input tone markers on top of simplified or traditional Chinese.

While the present invention has been shown and described with reference to certain preferred embodiments thereof, it will be understood by those skilled in the art that various changes in form and details may be made therein without departing from the spirit and scope of the invention as defined by the appended claims.

What is claimed is:

1. A Chinese pinyin input apparatus comprising:
a user interface including keys for inputting pinyin;
a display section for displaying pinyin;
a memory for storing vowels with a tone marker to correspond to respective keys on the user interface; and
a control section for, when a vowel that can have a tone marker is input, displaying a series of vowels having a same sound as the inputvowel and having different tone markers, together with predetermined corresponding keys, on the display section, and when one of the predetermined keys corresponding is selected, displaying the vowel with a tone marker corresponding to the selected key.

2. The Chinese pinyin input apparatus of claim 1, wherein said predetermined keys are number keys.

3. The Chinese pinyin input apparatus of claim 1, wherein said predetermined keys are keys that are not assigned alphabetic characters for inputting pinyin.

4. The Chinese pinyin input apparatus of claim 1, wherein said control section displays a separate selection window to display the series of vowels having the same sound as the inputvowel and having the different tone markers, together with the corresponding keys, on said display section.

5. The Chinese pinyin input apparatus of claim 4, wherein when a key other than the predetermined keys corresponding to the series of vowels with the different tone markers is pressed while said selection window is displayed, said control section displays the vowel without a tone marker and performs a function corresponding to the input key.

6. A method for inputting Chinese pinyin, comprising the steps of:
determining whether a vowel that can have a tone marker is input;
when a vowel that can have a tone marker is input, displaying a series of vowels having a same sound as the input vowel and having different tone markers, together with predetermined corresponding keys, on a display section; and
when one of the keys corresponding to the series of vowels is selected, displaying the vowel with a tone marker corresponding to the selected key.

7. The method of claim 6, wherein said predetermined keys are number keys.

8. The method of claim 6, wherein said predetermined keys are keys not assigned alphabetic characters to input pinyin.

9. The method of claim 6, wherein, when a key other than the predetermined keys for inputting the displayed series of vowels is selected, the vowel without a tone marker is displayed and a function corresponding to the input key is performed.

10. A Chinese pinyin input apparatus comprising:
a user interface including keys for inputting pinyin;
a display section for displaying pinyin;
a memory for storing vowels with a tone marker that correspond to respective keys on the user interface; and
a control section for, when a vowel that can have a tone marker is input, activating predetermined keys for a predetermined period of time to enable a user to input the vowel with a tone marker, and when one of the activated keys, which correspond to a series of vowels having the same sound as the input vowel and having different tone markers, is selected within said predetermined period of time, displaying the vowel with a tone marker corresponding to the selected key.

11. The Chinese pinyin input apparatus of claim 10, wherein said predetermined keys are keys assigned alphabetic characters to input pinyin.

12. The Chinese pinyin input apparatus of claim 10, wherein said control section displays a separate selection window which shows a series of vowels having the same sound as the inputted one and having different tone markers, together with corresponding keys, when activating said predetermined keys.

13. The Chinese pinyin input apparatus of claim 10, wherein, when the one of the predetermined keys corresponding to the series of vowels with different tone markers is input after a lapse of the predetermined period of time, said control section displays an alphabetic character or performs a function corresponding to the input key.

14. A method for inputting Chinese pinyin, comprising the steps of:
determining whether a vowel that can have a tone marker is input;
when a vowel that can have a tone marker is input, activating predetermined keys for a predetermined period of time to enable a user to input the vowel with a tone marker; and
when one of the activated keys, which correspond to a series of vowels having a same sound as the inputvowel and having different tone markers, is selected within said predetermined period of time, displaying the vowel with a tone marker corresponding to the selected key.

15. The method of claim 14, wherein said predetermined keys are keys assigned alphabetic characters to input pinyin.

16. The method of claim 14, wherein a separate selection window is displayed to show the series of vowels having the same sound as the inputvowel and having different tone markers, together with the corresponding keys, when activating said predetermined keys.

17. The method of claim 14, wherein, when the one of the predetermined keys corresponding to the series of vowels with the different tone markers is input after a lapse of the predetermined period of time, an alphabetic character assigned to the input key is displayed or a function corresponding to the input key is performed.
